(19) United States
(12) Patent Application Publication
(10) Pub. No.: US 2023/0411469 A1
(43) Pub. Date: Dec. 21, 2023

(54) SEMICONDUCTOR STRUCTURE AND FORMATION METHOD THEREOF

(71) Applicant: Semiconductor Technology Innovation Center (Beijing) Corporation, Beijing (CN)

(72) Inventors: Han WANG, Beijing (CN); Weihai Bu, Beijing (CN)

(73) Assignee: Semiconductor Technology Innovation Center (Beijing) Corporation, Beijing (CN)

(21) Appl. No.: 18/241,356

(22) Filed: Sep. 1, 2023

Related U.S. Application Data
(63) Continuation of application No. PCT/CN2021/080841, filed on Mar. 15, 2021.

(51) Int. Cl. H01L 29/417; H01L 29/40; H01L 29/66; H01L 29/06; H01L 29/08; H01L 29/775

(52) U.S. Cl. CPC H01L 29/41733; H01L 29/401; H01L 29/66439; H01L 29/66742; H01L 29/78696; H01L 29/0653; H01L 29/0847; H01L 29/775; H01L 29/66553

(57) ABSTRACT

A semiconductor structure and a formation method thereof are provided. The structure includes: a channel structure layer, where the channel structure layer includes a plurality of first channel layers sequentially spaced apart from bottom to top, the first channel layers extend along a horizontal direction; gate structures stretching across the channel structure layer and surrounding the first channel layers; source/drain structures located on two sides of the gate structure, where the source/drain structure includes a first source/drain doped layer located on a side wall of the first channel layer; and source/drain plugs in contact with tops of the source/drain structures, where the source/drain plug is further in contact with at least one of a longitudinal side wall facing away from the gate structure, a side wall along a horizontal first side, and a side wall along a horizontal second side of the first source/drain doped layer.

### CROSS REFERENCE TO RELATED APPLICATIONS

This application is a continuation application of PCT Patent Application No. PCT/CN2021/080841, filed on Mar. 15, 2021, the entire content of which is incorporated herein by reference.

### TECHNICAL FIELD

The present disclosure relates to the field of semiconductor manufacturing, in particular to a semiconductor structure and a formation method thereof.

### BACKGROUND

With rapid development of semiconductor manufacturing technologies, semiconductor devices are developing with higher component density and higher integration level, and semiconductor process nodes become smaller and smaller in accordance with a development trend following the Moore's Law. As the most basic semiconductor device, transistors are widely used at present. Therefore, with the increase of component density and integration level of semiconductor devices, channels of transistors have to be continuously shortened so as to adapt to size reduction of the process nodes.

In order to better adapt to the requirement that the size of the device is scaled down, in semiconductor technologies, there is a gradual transition from planar transistors to three-dimensional transistors with higher efficiency, for example, gate-all-around (Gate-all-around, GAA) transistors. In a gate-all-around transistor, a gate encircles a region where a channel is located from all sides. Compared with a gate of a planar transistor, the gate of the gate-all-around transistor has a higher capability of controlling the channel and can better inhibit a short-channel effect.

However, the performance of gate-all-around transistors still needs to be improved at present.

### SUMMARY

The present disclosure relates to a semiconductor structure and a formation method thereof to increase a drive current of a device and optimize performance of the semiconductor structure.

In an aspect of the disclosure, a semiconductor structure is provided. In one form, the semiconductor structure may include:
a base;
a channel structure layer located on the base, where the channel structure layer includes a plurality of first channel layers sequentially spaced apart from bottom to top, the first channel layers extend along a horizontal direction, and a direction parallel to the base and perpendicular to the horizontal direction is a longitudinal direction;
gate structures stretching across the channel structure layer and surrounding the first channel layers, where the gate structures fill a space between adjacent first channel layers and a space between the base and the first channel layer adjacent to the base;
source/drain structures located on two sides of the gate structure and covering a side wall of the channel structure layer, where the source/drain structure includes a first source/drain doped layer located on a side wall of the first channel layer along the horizontal direction; and
source/drain plugs located on two sides of the gate structure and in contact with tops of the source/drain structures, where the source/drain plug is further in contact with at least one of a longitudinal side wall facing away from the gate structure, a side wall along a horizontal first side, and a side wall along a horizontal second side of the first source/drain doped layer.

In another aspect of the disclosure, a method for forming a semiconductor structure is provided. In one form, the method may include:
providing a base, where a laminate structure is formed on the base and includes a plurality of channel laminates sequentially stacked from bottom to top, each channel laminate includes a sacrificial layer and a first channel layer located on the sacrificial layer, the first channel layer extends along a horizontal direction, and a direction parallel to the base and perpendicular to the horizontal direction is a longitudinal direction;
forming a dummy gate structure stretching across the laminate structure on the base;
forming grooves in parts, on two sides of the dummy gate structure, of the laminate structure;
forming a source/drain structure in the groove, where the source/drain structure includes a first source/drain doped layer covering a side wall of the first channel layer exposed out of the groove;
removing the dummy gate structure and forming a gate opening to expose the channel laminate;
removing the sacrificial layer in the channel laminate via the gate opening, such that the adjacent first channel layers as well as the base and the first channel layer adjacent to the base are surrounded to form a through groove;
forming gate structures in the gate opening and the through groove to surround the first channel layer; and
forming source/drain plugs on two sides of the gate structure, where the source/drain plug is in contact with a top of the source/drain structure, and the source/drain plug is further in contact with at least one of a longitudinal side wall facing away from the gate structure, a side wall along a horizontal first side and a side wall along a horizontal second side of the first source/drain doped layer.

Compared with the prior art, the present disclosure have at least the following advantages: According to the semiconductor structure described in the present disclosure, the source/drain plug is in contact with the top of the source/drain structure, and the source/drain plug is further in contact with at least one of the longitudinal side wall facing away from the gate structure, the side wall along the horizontal first side and the side wall along the horizontal second side of the first source/drain doped layer. As compared with a solution in which the source/drain plug is in contact with only the top of the source/drain doped layer, the source/drain plug and the first source/drain doped layer described in the present disclosure further have a contact surface along a direction perpendicular to a surface of the base, and the source/drain plug can be in contact with all the first source/drain doped layers located on side walls of the first channel layers. During work of a device, the current can correspondingly directly flow to each first channel layer through the side wall of the first source/drain doped layer by the source/drain plug, thereby avoiding flowing of the current along a direction perpendicular to the base in the source/drain structure. A material of the source/drain plug has a significantly smaller resistivity than a material of the source/drain structure, so that the current directly flows to each first channel layer through the source/drain plug, facilitating reduction of parasitic resistance, correspondingly reducing a voltage drop consumed in a route through which the current flows to each first channel layer, increasing a channel current value in each first channel layer, and especially significantly increasing the channel current value in the first channel layer closer to the base, thereby increasing a drive current of the device and optimizing the performance of the semiconductor structure.

According to the formation method of a semiconductor structure described in the present disclosure, the source/drain plugs are formed on two sides of the gate structure and are in contact with the tops of the source/drain structures, and the source/drain plug is further in contact with at least one of the longitudinal side wall facing away from the gate structure, the side wall along the horizontal first side and the side wall along the horizontal second side of the first source/drain doped layer. As compared with a solution in which the source/drain plug is in contact with only the top of the source/drain doped layer, the source/drain plug and the first source/drain doped layer described in the present disclosure further have a contact surface along a direction perpendicular to a surface of the base, and the source/drain plug can be in contact with all the first source/drain doped layers located on side walls of the first channel layers. During work of a device, the current can correspondingly directly flow to each first channel layer through the side wall of the first source/drain doped layer by the source/drain plug, thereby avoiding flowing of the current along a direction perpendicular to the base in the source/drain structure. A material of the source/drain plug has a significantly smaller resistivity than a material of the source/drain structure, so that the current directly flows to each first channel layer through the source/drain plug, facilitating reduction of parasitic resistance, correspondingly reducing a voltage drop consumed in a route through which the current flows to each first channel layer, increasing a channel current value in each first channel layer, and especially significantly increasing the channel current value in the first channel layer closer to the base, thereby increasing a drive current of the device and optimizing the performance of the semiconductor structure.

### BRIEF DESCRIPTION OF THE DRAWINGS

FIG. 1 is a schematic diagram of a partial three-dimensional structure of a semiconductor structure.

FIG. 2 and FIG. 3 are schematic structural diagrams of a semiconductor structure.

FIG. 4 to FIG. 20 are schematic structural diagrams corresponding to steps of a formation method of a semiconductor structure.

### DETAILED DESCRIPTION

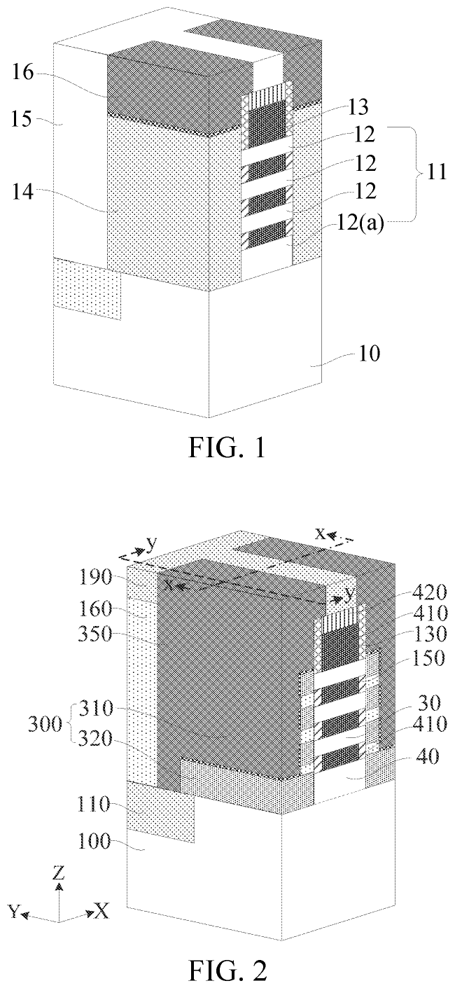

Reasons for improving performance of gate-all-around transistors are analyzed with reference to a semiconductor structure. FIG. 1 is a schematic diagram of a partial three-dimensional structure of a semiconductor structure.

The semiconductor structure includes: a base 10; a channel structure layer 11 located on the base 10, where the channel structure layer 11 includes a plurality of channel layers 12 sequentially spaced apart from bottom to top; gate structures 13 stretching across the channel structure layer 11 and covering a top of the channel structure layer 11, where the gate structures 13 fill a space between adjacent first channel layers 12 and surround the channel layers 12; source/drain doped layers 14 located on two sides of the gate structure 13 and covering a side wall of the channel structure layer 11; a dielectric layer 15 located on the base 10 and covering the source/drain doped layer 14; and a source/drain plug 16 located in the dielectric layer 15 at a top of the source/drain doped layer 14 and in contact with the top of the source/drain doped layer 14.

The semiconductor structure is a gate-all-around transistor. During work of the gate-all-around transistor, external current sequentially flows through the source/drain plug 16 located on a first side of the gate structure 13, the source/drain doped layer 14 located on the first side of the gate structure 13, the channel layer 12, the source/drain doped layer 14 located on a second side of the gate structure 13, and the source/drain plug 16 located on the second side of the gate structure 13, and finally flows out of a device.

For a channel layer 12 far away from the source/drain plug 16, for example, a bottom channel layer 12(a) (that is, the channel layer 12 closest to the base 10), along a direction perpendicular to the base 10, current needs to flow through a long route in the source/drain doped layer 14, and the source/drain doped layer 14 has large parasitic resistance in this long flowing route, so that a large voltage drop is consumed, leading to a small channel current flowing through the channel layer 12 farther away from the source/drain plug 16, and being not conducive to increase of a drive current of a device.

In order to address the above problem, one solution is to increase an ion doping concentration of the source/drain doped layer so as to reduce resistance of the source/drain doped layer. However, in a semiconductor technology, the source/drain doped layer is usually formed by using an epitaxy process, and increase of the ion doping concentration may affect growth quality of an epitaxial layer during the epitaxy process, thereby leading to reduction of a film forming quality of the source/drain doped layer.

Another solution is to increase a projection area of the source/drain doped layer on the base. This correspondingly increases a cross section area of a conductive region, facilitating reduction of resistance of the source/drain doped layer and the source/drain plug. However, the increase of the projection area of the source/drain doped layer on the base may lead to increase of a design size, which is not conductive to reducing a manufacturing cost and a device size.

Therefore, the above two solutions both cannot solve the problem about small channel current in the channel layer farther away from the source/drain plug.

In order to address the above technical problem, an implementation of the present disclosure provides a semiconductor structure, the source/drain plug is in contact with the top of the source/drain structure; and in addition, the source/drain plug is further in contact with at least one of the longitudinal side wall facing away from the gate structure, the side wall along the horizontal first side and the side wall along the horizontal second side of the first source/drain doped layer. As compared with a solution in which the source/drain plug is in contact with only the top of the source/drain doped layer, the source/drain plug and the first source/drain doped layer provided by the implementations of the present disclosure further have a contact surface along a direction perpendicular to a surface of the base, and the source/drain plug can be in contact with all the first source/drain doped layers located on side walls of the first channel layers. During work of a device, the current can correspondingly directly flow to each first channel layer through the side wall of the first source/drain doped layer by the source/drain plug, thereby avoiding flowing of the current along a direction perpendicular to the base in the source/drain structure. A material of the source/drain plug has a significantly smaller resistivity than a material of the source/drain structure, so that the current directly flows to each first channel layer through the source/drain plug, facilitating reduction of parasitic resistance, correspondingly reducing a voltage drop consumed in a route through which the current flows to each first channel layer, increasing a channel current value in each first channel layer, and especially significantly increasing the channel current value in the first channel layer closer to the base, thereby increasing a drive current of the device and optimizing the performance of the semiconductor structure.

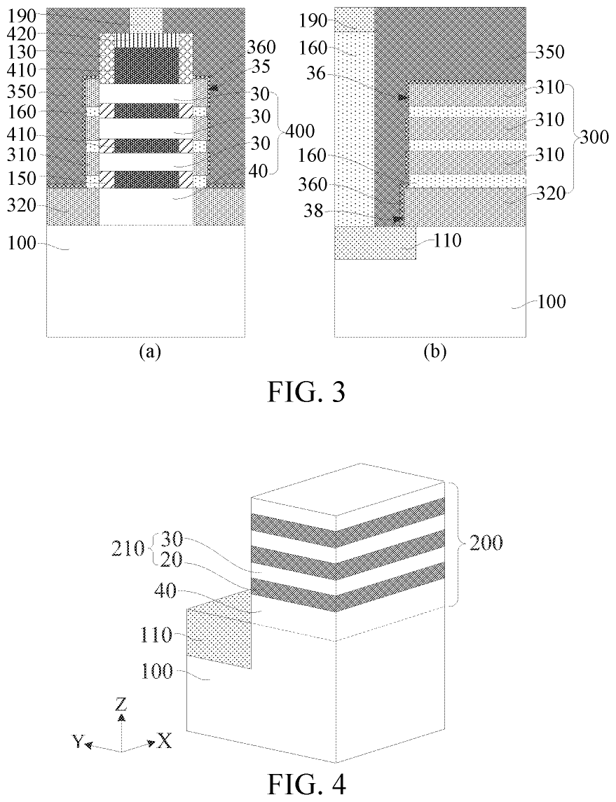

To make the foregoing objectives, features, and advantages of the implementations of the present disclosure more apparent and easier to understand, specific implementations of the present disclosure are described in detail below with reference to the accompanying drawings. Refer to FIG. 2 and FIG. 3. FIG. 2 is a schematic diagram of a partial three-dimensional structure. FIG. 3(a) is a cross-sectional view of FIG. 2 along a direction xx, and FIG. 3(b) is a cross-sectional view of FIG. 2 along a direction yy, showing a schematic structural diagram of a semiconductor structure according to an implementation of the present disclosure.

As shown in FIG. 2 and FIG. 3, in this implementation, the semiconductor structure includes: a base 100; a channel structure layer 400 located on the base 100, where the channel structure layer 400 includes a plurality of first channel layers 30 sequentially spaced apart from bottom to top, the first channel layers 30 extend along a horizontal direction (as indicated by a direction X in FIG. 2), and a direction parallel to the base 100 and perpendicular to the horizontal direction is a longitudinal direction (as indicated by a direction Y in FIG. 2); gate structures 410 stretching across the channel structure layer 400 and surrounding the first channel layers 30, where the gate structures 410 fill a space between adjacent first channel layers 30 and a space between the base 100 and the first channel layer 30 adjacent to the base 100; source/drain structures 300 located on two sides of the gate structure 410 and covering a side wall of the channel structure layer 400, where the source/drain structure 300 includes a first source/drain doped layer 310 located on a side wall of the first channel layer 30 along the horizontal direction; and source/drain plugs 350 located on two sides of the gate structure 410 and in contact with tops of the source/drain structures 300, where the source/drain plug 350 is further in contact with at least one of a longitudinal side wall 35 facing away from the gate structure 410, a side wall 36 along a horizontal first side, and a side wall (not shown in the figure) along a horizontal second side of the first source/drain doped layer 310.

The source/drain plug 350 is in contact with a top of the source/drain structure 300; and in addition, the source/drain plug 350 is further in contact with at least one of a longitudinal side wall 35 facing away from the gate structure 410, a side wall 36 along a horizontal first side and a side wall along a horizontal second side of the first source/drain doped layer 310. As compared with a solution in which the source/drain plug is in contact with only the top of the source/drain doped layer, the source/drain plug 350 and the first source/drain doped layer 310 provided by this implementation further have a contact surface along a direction (as indicated by a direction Z in FIG. 2) perpendicular to a surface of the base 100, and the source/drain plug 350 can be in contact with all the first source/drain doped layers 310 located on side walls of the first channel layers 30. During work of a device, the current can correspondingly directly flow to each first channel layer 30 through the side wall of the first source/drain doped layer 310 by the source/drain plug 350, thereby avoiding flowing of the current along a direction perpendicular to the base 100 in the source/drain structure 300. A material of the source/drain plug 350 has a significantly smaller resistivity than a material of the source/drain structure, so that the current directly flows to each first channel layer 30 through the source/drain plug 350, facilitating reduction of parasitic resistance, correspondingly reducing a voltage drop consumed in a route through which the current flows to each first channel layer 30, increasing a channel current value in each first channel layer 30, and especially significantly increasing the channel current value in the first channel layer 30 closer to the base 100, thereby increasing a drive current of the device and optimizing the performance of the semiconductor structure.

The base 100 is configured to provide a process platform for a formation procedure of the semiconductor structure. In this implementation, the semiconductor structure being a gate-all-around (GAA) transistor is used as an example for description. In other implementations, the semiconductor structure may alternatively be a forksheet gate transistor (Forksheet) or a complementary field effect transistor (CFET).

In this implementation, the base 100 is a silicon substrate. In other implementations, the base may also be made of another material such as germanium, silicon germanide, silicon carbide, gallium arsenide, or indium gallide; and the base may also be another type of substrate, for example, a silicon substrate on an insulator or a germanium substrate on an insulator.

The channel structure layer 400 is configured to provide a conducting channel for a field effect transistor.

In an example, the channel structure layer 400 is a fin structure extending along the horizontal direction.

A stacking direction (as indicated by a direction Z in FIG. 2) of a plurality of first channel layers 30 that are sequentially spaced apart from bottom to top is perpendicular to a surface of the base 100.

In this implementation, the semiconductor structure is an NMOS transistor, and the first channel layer 30 is made of Si. In other implementations, when the semiconductor structure is a PMOS transistor, in order to improve the performance of the PMOS transistor, a SiGe channel technology may be adopted, and the first channel layer is made of SiGe.

In an example, there are three first channel layers 30 in the channel structure layer 400. In other implementations, the first channel layer may be provided in another quantity.

In an example, the channel structure layer 400 further includes: a second channel layer 40 located between the base 100 and the first channel layer 30 and spaced apart from the first channel layer 30. The second channel layer 40 is also configured to provide a conducting channel for a field effect transistor.

In this implementation, the second channel layer 40 and the first channel layer 30 are made of a same material, where the second channel layer 40 is made of silicon.

In this implementation, the semiconductor structure further includes: an isolation structure 110 located in part of thickness of the base 100 at a side portion of the channel structure layer 400. The isolation structure 110 is configured to isolate the adjacent channel structure layers 400.

In this implementation, the isolation structure 110 is made of silicon oxide. The isolation structure 110 may also be made of another insulating material.

Specifically, the base 100 includes a substrate (unmarked) and a protrusion (unmarked) protruding from the substrate. The isolation structure 110 is located on the substrate at a side portion of the protrusion, and the isolation structure 110 exposes the channel structure layer 400. Correspondingly, the isolation structure 110 is further configured to define an active area (Active Area, AA) and an isolation area of the base 100.

In an example, the protrusion and the second channel layer 40 are an integrally formed structure.

It would be appreciated that the implementation is described by way of example in which the channel structure layer 400 further includes the second channel layer 40. In other implementations, the channel structure layer may alternatively include only the first channel layer according to actual process requirements. Correspondingly, a top surface of the isolation structure is flush with a top surface of the protrusion.

During work of the device, the gate structure 410 is configured to control on and off of the conducting channel.

In this implementation, the gate structure 410 fills a space between the adjacent first channel layers 30 and a space between the second channel layer 40 and the first channel layer 30 adjacent to the second channel layer 40.

In this implementation, the gate structure 410 is a metal gate structure. The gate structure 410 includes a high-k gate dielectric layer (not shown in the figure), a work function layer (not shown in the figure) located on the high-k gate dielectric layer, and a gate electrode layer (not shown in the figure) located on the work function layer.

The high-k gate dielectric layer is configured to implement electrical isolation between the work function layer and the channel and between the gate electrode layer and the channel. The high-k gate dielectric layer is made of a high-k dielectric material. The high-k gate dielectric layer may alternatively be made of a material selected from ZrO₂, HfSiO, HfSiON, HfTaO, HfTiO, HfZrO, or Al₂O₃.

The work function layer is configured to adjust a work function of the gate structure 410 so as to adjust a voltage threshold of the field effect transistor. During formation of an NMOS transistor, the work function layer is an N-type work function layer, and the work function layer is made of one or more of titanium aluminide, tantalum carbide, aluminum, or titanium carbide. During formation of a PMOS transistor, the work function layer is a P-type work function layer, and the work function layer is made of one or more of titanium nitride, tantalum nitride, titanium carbide, tantalum silicon nitride, titanium silicon nitride, and tantalum carbide.

The gate electrode layer is an external electrode of the gate structure 410 to be electrically connected to an external circuit. The gate electrode layer is made of a conductive material, for example, W, Al, Cu, Ag, Au, Pt, Ni, or Ti.

In this implementation, the gate structure 410 includes a first part (unmarked) stretching across the channel structure layer 400, and a second part (unmarked) that fills a space between the adjacent first channel layers 30 and a space between the second channel layer 40 and the first channel layer 30 adjacent to the second channel layer 40.

In this implementation, along the horizontal direction, side walls of the first part and second part are recessed with respect to a side wall of the first channel layer 30 at a same side so as to provide spaces for a gate side wall and an inner spacer.

In this implementation, along the horizontal direction, the side wall of the first part is recessed with respect to the side wall of the first channel layer 30 at the same side so as to provide a spatial position for the gate side wall. The semiconductor structure further includes: a gate side wall 130 located on the side wall of the first part and covering part of the top of the channel structure layer 400.

The gate side wall 130 is configured to define a formation position of the source/drain structure 300, and the gate side wall 130 is further configured to protect a side wall of the gate structure 410.

In this implementation, the gate side wall 130 is made of silicon nitride, silicon oxide, silicon oxynitride, a low-k dielectric material, or an ultralow-k dielectric material, and the gate side wall 130 is a single-layer or laminate structure. In an example, the gate side wall 130 is a single-layer structure made of silicon nitride.

In this implementation, along the horizontal direction, the side wall of the second part is recessed with respect to the side wall of the first channel layer 30 at the same side so as to provide a spatial position for the inner spacer. The semiconductor structure further includes: an inner spacer 150, where the inner spacer 150 fills a region enclosed by the second part and the adjacent first channel layer 30, and a region enclosed by the second part, the base 100 and the first channel layer 30 adjacent to the base 100.

Specifically, the inner spacer 150 fills a region enclosed by the second part and the adjacent first channel layer 30, and a region enclosed by the second part, the second channel layer 40 and the first channel layer 30 adjacent to the second channel layer 40.

The inner spacer 150 is configured to isolate the source/drain structure 300 from the gate structure 410, as well as to increase a distance between the gate structure 410 and the source/drain structure 300, helping to reduce parasitic capacitance between the gate structure 410 and the source/drain structure 300.

In this implementation, the inner spacer 150 is made of an insulating material for isolating the source/drain structure 300 from the gate structure 410. In this implementation, the inner spacer 150 is made of silicon nitride, silicon oxide, silicon oxynitride, a low-k dielectric material, or an ultralow-k dielectric material. In an example, the inner spacer 150 is made of silicon nitride.

In this implementation, the semiconductor structure further includes: an etch stop layer 420 located at the top of the gate structure 410. The etch stop layer 420 is configured to protect the top of the gate structure 410 so as to prevent mistaken etching of the gate structure 410 during formation of the source/drain plug 350, thereby helping to avoid bridging of the source/drain plug 350 and the gate structure 410.

In this implementation, the gate side wall 130 covers the side wall of the first part and a side wall of the etch stop layer 420.

The etch stop layer 420 is made of a material that has etching selectivity with a material of the interlayer dielectric layer 160, so as to ensure that an etching process for forming the source/drain plug 350 is unlikely to cause mistaken etching of the etch stop layer 420.

In this implementation, the etch stop layer 420 is made of one or more of silicon nitride, silicon carbide, silicon carbonitride, silicon oxy-carbonitride, silicon oxynitride, boron nitride, and boron carbonitride. In an example, the etch stop layer 420 is made of silicon carbide.

The source/drain structure 300 is used as a source or a drain of a field effect transistor, and is configured to provide a current carrier source during work of the field effect transistor.

In this implementation, the resistance of the source/drain structure is reduced to increase the channel current in the channel layer without increasing the ion doping concentration of the source/drain structure, correspondingly helping to guarantee epitaxial growth quality of an epitaxy process for forming the source/drain structure 300, thereby improving the film forming quality of the source/drain structure 300 and facilitating optimization of the performance of the semiconductor structure.

In addition, in this implementation, the resistance of the source/drain structure is reduced to increase the channel current in the channel layer without increasing a projection area of the source/drain structure on the base, correspondingly facilitating miniaturization of the device size and also facilitating reduction of the manufacturing cost.

In this implementation, the source/drain structure 300 includes an ion-doped stress layer, where the stress layer is configured to provide stress for a channel region, thereby increasing a carrier mobility.

Specifically, the first source/drain doped layer 310 is configured to provide stress for the first channel layer 30.

In this implementation, during formation of a PMOS transistor, the source/drain structure 300 includes a P-type ion doped stress layer made of Si or SiGe. During formation of an NMOS transistor, the source/drain structure 300 includes an N-type ion doped stress layer made of Si or SiC.

In an implementation, the first source/drain doped layers 310 located on side walls of the adjacent first channel layers 30 are spaced apart. When the source/drain plug 350 is further in contact with the longitudinal side wall facing away from the gate structure 410, the side wall along the horizontal first side and the side wall along the horizontal second side of the first source/drain doped layer 310, the first source/drain doped layers 310 on the side walls of the adjacent first channel layers 30 have no contact with each other, so that during work of the device, current is prevented from flowing in a direction (as indicated by a direction Z in FIG. 2) perpendicular to the base 100 in the source/drain structure 300, and thus the current flows to each first channel layer 30 through only the source/drain plug 350, correspondingly significantly reducing a voltage drop consumed in a route through which the current flows to each first channel layer 30, increasing the channel current value in each first channel layer 30, and especially significantly increasing the channel current value in the first channel layer 30 closer to the base 100.

In other implementations, the first source/drain doped layers on the side walls of the adjacent first channel layers can also be in contact with each other. When the semiconductor structure generally further includes an interlayer dielectric layer covering the source/drain structure, the interlayer dielectric layer correspondingly does not need to fill a gap between the first source/drain doped layers on the side walls of the adjacent first channel layers, helping to reduce a technological difficulty for forming the interlayer dielectric layer, and correspondingly improving the technological compatibility and the film forming quality of the interlayer dielectric layer.

In this implementation, the side wall 36 along the horizontal first side of the first source/drain doped layer 310 faces away from the side wall (not shown in the figure) along the horizontal second side in the longitudinal direction.

In this implementation, the source/drain structure 400 further includes: a second source/drain doped layer 320 located on a side wall of the second channel layer 40 along the horizontal direction, where the second source/drain doped layer 320 is further located on a top surface of the base 100 on two sides of the second channel layer 40, and along the horizontal direction, an end portion of the second source/drain doped layer 320 protrudes out of an end portion of the first source/drain doped layer 310.

The second source/drain doped layer 320 is configured to provide stress for the second channel layer 40, thereby increasing a carrier mobility in the second channel layer 40.

In this implementation, the second source/drain doped layer 320 and the first source/drain doped layer 310 are made of a same material, and are also the same in doping type.

In this implementation, along the horizontal direction, the end portion of the second source/drain doped layer 320 protrudes out of the end portion of the first source/drain doped layer 310, ensuring that there is still a space, for forming the source/drain plug 350, in a region enclosed by the top of the second source/drain doped layer 320 and a side portion of the first source/drain doped layer 310, helping the source/drain plug 350 to have a small size along the horizontal direction, and helping to reduce a horizontal area occupied by the source/drain plug 350, thereby helping to reduce the size of the semiconductor structure. In addition, the second source/drain doped layer 320 is further located on the top surface of the base 100 on the two sides of the second channel layer 40, and correspondingly the source/drain plug 350 can be in contact with the top of the second source/drain doped layer 320, not only implementing electric connection between the source/drain plug 350 and the second source/drain doped layer 320, but also preventing contact between the source/drain plug 350 and the base 100. Besides, the source/drain plug 350 is enabled to come into contact with the longitudinal side wall, facing away from the gate structure 410, of the first source/drain doped layer 310. Compared with the horizontal side wall of the first source/drain doped layer 310, the longitudinal side wall of the first source/drain doped layer 310 has a larger area, so that a contact area between the source/drain plug 350 and the first source/drain doped layer 310 is increased.

It would be appreciated that along the horizontal direction, the width of the first source/drain doped layer 310 should not be too small or too large. If the width of the first source/drain doped layer 310 along the horizontal direction is too small, a volume of the first source/drain doped layer 310 is correspondingly too small, which is likely to affect stress of the first source/drain doped layer 310. In addition, the semiconductor structure usually further includes a silicide layer between the first source/drain doped layer 310 and the source/drain plug 350, a formation process of the silicide layer usually also consumes part of the first source/drain doped layer 310, and a too small width of the first source/drain doped layer 310 along the horizontal direction may cause an adverse effect to the performance of the semiconductor structure. If the width of the first source/drain doped layer 310 along the horizontal direction is too large, a top area of the second source/drain doped layer 320 exposed out of the first source/drain doped layer 310 is too small, and a space enclosed by the top of the second source/drain doped layer 320 and the side portion of the first source/drain doped layer 310 is too small. When the source/drain plug 350 is formed in the space enclosed by the top of the second source/drain doped layer 320 and the side portion of the first source/drain doped layer 310, the space for forming the source/drain plug 350 may be too small, and this is likely to increase a forming difficulty of the source/drain plug 350. Therefore, in this implementation, along the horizontal direction, the width of the first source/drain doped layer 310 is 10% to 90% of the width of the second source/drain doped layer 320.

In an implementation, the second source/drain doped layer 320 and the first source/drain doped layer 310 are spaced apart. Correspondingly, when the source/drain plug 350 is at least in contact with the tops of the first source/drain doped layer 310 and second source/drain doped layer 320 as well as the longitudinal side wall, facing away from the gate structure 410, of the first source/drain doped layer 310, the second source/drain doped layer 320 and the first source/drain doped layer 310 have no contact with each other, so that during work of the device, current is prevented from flowing in a direction (as indicated by a direction Z in FIG. 2) perpendicular to the base 100 in the source/drain structure 300, and thus the current flows to the second channel layer 40 through only the source/drain plug 350, correspondingly significantly reducing a voltage drop consumed in a route through which the current flows to the second channel layer 40, and significantly increasing the channel current value in the second channel layer 40.

In other implementations, the second source/drain doped layer and the first source/drain doped layer may also be in contact with each other, so that the interlayer dielectric layer does not need to fill a gap between the second source/drain doped layer and the first source/drain doped layer, helping to reduce a forming difficulty of the interlayer dielectric layer, and correspondingly improving the technological compatibility and the film forming quality of the interlayer dielectric layer.

It would be appreciated that this implementation is described by using an example in which the channel structure layer 400 further includes the second channel layer 40, and correspondingly the source/drain structure 300 further includes the second source/drain doped layer 320 located on the side wall of the second channel layer 40. In other implementations, when a channel structure layer includes only a plurality of channel laminates sequentially stacked from bottom to top, a source/drain structure correspondingly includes only a first source/drain doped layer located on a side wall of a first channel layer.

In this implementation, the semiconductor structure further includes: an interlayer dielectric layer 160 located on the base 100 at a side portion of the gate structure 410, where the interlayer dielectric layer 160 covers the source/drain structure 300 and also fills a space between the adjacent first channel layers 30.

The interlayer dielectric layer 160 is configured to isolate adjacent devices. In this implementation, the interlayer dielectric layer 160 is made of silicon oxide. The interlayer dielectric layer 160 may alternatively be made of another insulating material.

In this implementation, the first source/drain doped layers 310 located on the side walls of the adjacent first channel layers 30 are spaced apart, and correspondingly the interlayer dielectric layer 160 further fills a space between the adjacent first source/drain doped layers 310. In this implementation, the source/drain structure 300 further includes a second source/drain doped layer 320, the second source/drain doped layer 320 and the adjacent first source/drain doped layer 310 are spaced apart, and correspondingly the interlayer dielectric layer 160 further fills a space between the second source/drain doped layer 320 and the adjacent first source/drain doped layer 310.

In this implementation, the semiconductor structure further includes: a metal dielectric layer 190 located on the interlayer dielectric layer 160 and covering the top of the gate structure 410. Specifically, the metal dielectric layer 190 covers the etch stop layer 420 located at the top of the gate structure 410.

The metal dielectric layer 190 is configured to isolate the source/drain plugs 350. The metal dielectric layer 190 is made of a dielectric material, for example, one or more of silicon oxide, silicon nitride, silicon oxynitride, silicon oxycarbide, silicon carbonitride, silicon oxy-carbonitride, a low-k dielectric material, and an ultralow-k dielectric material.

The source/drain plug 350 is configured to implement electric connection between the source/drain structure 300 and an external circuit or other interconnected structures. The source/drain plug 350 is made of a conductive material, for example, one or more of Cu, Co, Ru, RuN, W, and Al.

In an example, along the horizontal direction, the end portion of the second source/drain doped layer 320 protrudes out of the end portion of the first source/drain doped layer 310. Correspondingly, the source/drain plug 350 is at least in contact with the tops of the first source/drain doped layer 310 and second source/drain doped layer 320 as well as the longitudinal side wall, facing away from the gate structure 410, of the first source/drain doped layer 310.

Compared with the first channel layer 30, the second channel layer 40 is closer to the base 100. The second channel layer 40 is a lowermost channel layer in the channel structure layer 400. The source/drain plug 350 is in contact with the top of the source/drain doped layer 320, so that the source/drain plug 350 is electrically connected to the second source/drain doped layer 320, thus current can directly flow to the second channel layer 40 through the source/drain plug 350, thereby significantly increasing the channel current in the second channel layer 40. In addition, contact between the source/drain plug 350 and the base 100 at the bottom of the second source/drain doped layer 320 is also prevented.

In addition, compared with the side wall along the horizontal first side or the side wall along the horizontal second side of the first source/drain doped layer 310, the longitudinal side wall, facing away from the gate structure 410, of the first source/drain doped layer 310 has a larger area; and the source/drain plug 350 is in contact with the longitudinal side wall, facing away from the gate structure 410, of the first source/drain doped layer 310, helping to ensure that the source/drain plug 350 does not have a too large volume and also increasing a contact area between the source/drain plug 350 and the first source/drain doped layer 310, thereby reducing contact resistance of the source/drain plug 350 and the first source/drain doped layer 310.

In an example, the source/drain plug 350 is further in contact with at least one of a side wall 38 along a horizontal first side and a side wall (not shown in the figure) along a horizontal second side of the second source/drain doped layer 320, helping to increase a contact area between the source/drain plug 350 and the second source/drain doped layer 320, and correspondingly reducing contact resistance of the source/drain plug 350 and the second source/drain doped layer 320.

In an implementation, the source/drain plug 350 is in contact with all the tops of the first source/drain doped layer 310 and second source/drain doped layer 320, the longitudinal side wall 35, facing away from the gate structure 410, of the first source/drain doped layer 310, the side wall 36 along the horizontal first side and the side wall along the horizontal second side of the first source/drain doped layer 310, as well as the side wall 36 along the horizontal first side and the side wall along the horizontal second side of the second source/drain doped layer 320, so that the source/drain plug 350 can be in contact with all the top and side walls of the exposed first source/drain doped layer 310 as well as the top and side walls of the exposed second source/drain doped layer 320, helping to significantly increase a contact area between the source/drain plug 350 and the first source/drain doped layer 310 and a contact area between the source/drain plug 350 and the second source/drain doped layer 320, thereby significantly reducing contact resistance of the source/drain plug 350 and the source/drain structure 300, and improving the performance of the semiconductor structure.

In this implementation, the source/drain plug 350 penetrates through the interlayer dielectric layer 160 at the top of the source/drain structure 300. Specifically, the source/drain plug 350 further penetrates through a metal dielectric layer 190 at an upper portion of the source/drain structure 300.

In this implementation, when the source/drain plug 350 covers the horizontal side wall of the second source/drain doped layer 320, the source/drain plug 350 is located, along the longitudinal direction, at part of the isolation structure 110 that is adjacent to a corresponding side wall of the second source/drain doped layer 320.

In this implementation, the semiconductor structure further includes: a silicide layer 360 located between the source/drain plug 350 and a surface of the source/drain structure 300.

The silicide layer 360 is configured to reduce contact resistance between the source/drain plug 350 and the source/drain structure 300. In addition, during work of the device, current flows through a surface of the silicide layer 360 via the source/drain plug 350, in other words, the current can flow through the surface of the source/drain structure 300 in contact with the source/drain plug 350 and thus flows to each channel layer. In this implementation, the current can flow through the surface of the source/drain structure 300 in contact with the source/drain plug 350 and thus flows to the second channel layer 40 and each first channel layer 30.

In this implementation, the silicide layer 360 may be made of a nickel-silicon compound, a cobalt-silicon compound, or a titanium-silicon compound.

Correspondingly, the present disclosure further provides a formation method of a semiconductor structure. FIG. 4 to FIG. 20 are schematic structural diagrams corresponding to steps of a formation method of a semiconductor structure according to an implementation of the present disclosure.

The following describes in detail the formation method of a semiconductor structure in this implementation with reference to the accompanying drawings.

FIG. 4 shows a schematic diagram of a partial three-dimensional structure. A base 100 is provided, where a laminate structure 200 is formed on the base 100 and includes a plurality of channel laminates 210 sequentially stacked from bottom to top. Each channel laminate 210 includes a sacrificial layer 20 and a first channel layer 30 located on the sacrificial layer 20, where the first channel layer 30 extends along a horizontal direction (as indicated by a direction X in FIG. 4), and a direction parallel to the base 100 and perpendicular to the horizontal direction is a longitudinal direction (as indicated by a direction Y in FIG. 4).

The base 100 is configured to provide a process platform for a subsequent procedure. In this implementation, formation of a gate-all-around (GAA) transistor is used as an example for description. In other implementations, the formation method may also be used for forming a forksheet gate transistor (Forksheet) or a complementary field effect transistor (CFET). In this implementation, the base 100 is a silicon substrate. In other implementations, the base may also be made of another material such as germanium, silicon germanide, silicon carbide, gallium arsenide, or indium gallide; and the base may also be another type of substrate, for example, a silicon substrate on an insulator or a germanium substrate on an insulator.

In an example, the laminate structure 200 is a fin structure extending along the horizontal direction.

In the laminate structure 200, a stacking direction (as indicated by a direction Z in FIG. 4) of a plurality of channel laminates 210 is perpendicular to a surface of the base 100.

The channel laminates 210 are configured to provide a technological basis for subsequent formation of suspended first channel layers 30 that are spaced part. Specifically, the first channel layer 30 is configured to provide a conducting channel for a field effect transistor. The sacrificial layer 20 is configured to support the first channel layer 30 so as to provide a technological basis for implementing formation of suspended and spaced first channel layers 30, and the sacrificial layer 20 is further configured to occupy a spatial position for subsequent formation of a gate structure.

In this implementation, for formation of an NMOS transistor, the first channel layer 30 is made of Si, and the sacrificial layer 20 is made of SiGe. In a subsequent process of removing the sacrificial layer 20, a high requirement is imposed for etching of SiGe and Si. Therefore, a method of making the sacrificial layer 20 of SiGe and making the first channel layer 30 of Si can effectively reduce the influence of a removal process of the sacrificial layer 20 on the first channel layer 30, so that quality of the first channel layer 30 is improved, thereby facilitating improvement of the performance of the device. In other implementations, during formation of a PMOS transistor, in order to improve the performance of the PMOS transistor, a SiGe channel technology may be adopted, in which the first channel layer is made of SiGe, and the sacrificial layer is made of Si.

In an example, there are three channel laminates 210. In other implementations, the channel laminate may be provided in another quantity.

In an example, the laminate structure 200 further includes a second channel layer 40 located between the base 100 and the channel laminate 210. The second channel layer 40 is also configured to provide a conducting channel for a field effect transistor.

In this implementation, the second channel layer 40 and the first channel layer 30 are made of a same material, where the second channel layer 40 is made of silicon.

In this implementation, an isolation structure 110 is further formed in the base 100 at a side portion of the laminate structure 200. The isolation structure 110 is configured to isolate the adjacent laminate structures 200.

In this implementation, the isolation structure 110 is made of silicon oxide. The isolation structure 110 may also be made of another insulating material.

Specifically, the base 100 includes a substrate (unmarked) and a protrusion (unmarked) protruding from the substrate. The isolation structure 110 is located on the substrate at a side portion of the protrusion, and the isolation structure 110 exposes the laminate structure 200. Correspondingly, the isolation structure 110 is further configured to define an active area (Active Area, AA) and an isolation area of the base 100.

In an example, the protrusion and the second channel layer 40 are an integrally formed structure. In an example, the protrusion is also a fin structure extending along the horizontal direction.

It would be appreciated that the implementation is described by using an example in which the laminate structure 200 further includes the second channel layer 40. In other implementations, the laminate structure may alternatively include only a plurality of channel laminates sequentially stacked from bottom to top according to actual process requirements. Correspondingly, a top surface of the isolation structure is flush with a top surface of the protrusion.

In an implementation, the step of providing the base 100 includes: providing a semiconductor layer (not shown in the figure) and a plurality of channel laminate materials (not shown in the figure) that are sequentially stacked from bottom to top on the semiconductor layer, where the channel laminate material includes an initial sacrificial layer and an initial first channel layer that is located on the initial sacrificial layer; patterning the channel laminate material and part of thickness of the semiconductor layer to form a substrate, a protrusion structure protruding from the substrate, and a plurality of channel laminates 210 that are sequentially stacked on the protrusion structure, where the protrusion structure includes the protrusion and the second channel layer 40 located on the protrusion, and the second channel layer 40 and the plurality of stacked channel laminates 210 are used to form the laminate structure 200; and forming an isolation structure 110 on a substrate at a side portion of the laminate structure 200, where the isolation structure 110 exposes the second channel layer 40 and the channel laminate 210.

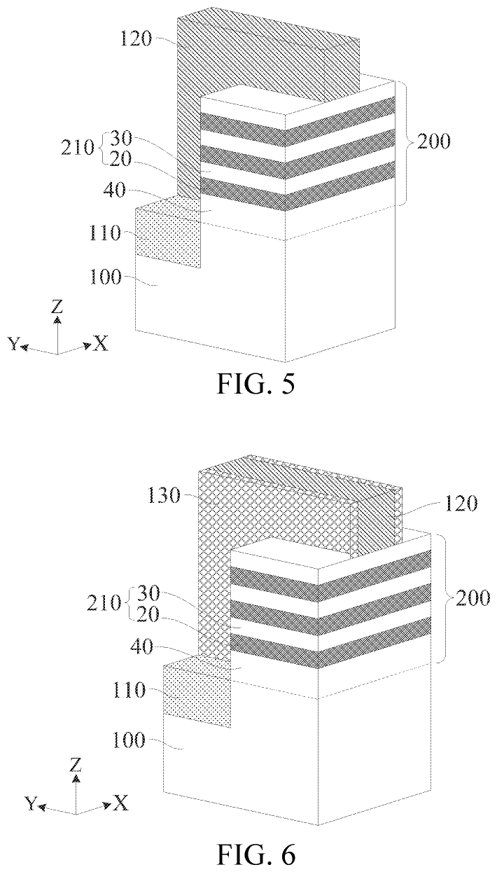

FIG. 5 shows a schematic diagram of a partial three-dimensional structure, where a dummy gate structure 120 stretching across the laminate structure 200 is formed on the base 100. Specifically, the dummy gate structure 120 is located on the isolation structure 110 and covers part of a top and part of a side wall of the laminate structure 200. The dummy gate structure 120 extends along the longitudinal direction.

The dummy gate structure 120 is configured to pre-occupy a spatial position for subsequent formation of a gate structure.

The dummy gate structure 120 may be a laminate structure or a single-layer structure. In this implementation, the dummy gate structure 120 is a laminate structure and includes a dummy gate oxide layer (not shown in the figure) and a dummy gate layer (not shown in the figure) located on the dummy gate oxide layer. Specifically, the dummy gate structure 120 is of a polysilicon gate structure, the dummy gate oxide layer may be made of silicon oxide or silicon oxynitride, and the dummy gate layer may be made of polysilicon.

FIG. 6 shows a partial three-dimensional diagram. The formation method further includes: forming a gate side wall 130 on a side wall of the dummy gate structure 120. The gate side wall 130, together with the dummy gate structure 120, is used as an etch mask for an etching process for subsequent formation of a groove, so as to define a formation position of the source/drain structure, and the gate side wall 130 is further configured to protect the dummy gate structure 120 and a side wall of a subsequent gate structure.

In this implementation, the gate side wall 130 is made of silicon nitride, silicon oxide, silicon oxynitride, a low-k dielectric material, or an ultralow-k dielectric material, and the gate side wall 130 is a single-layer or laminate structure. In an example, the gate side wall 130 is a single-layer structure made of silicon nitride.

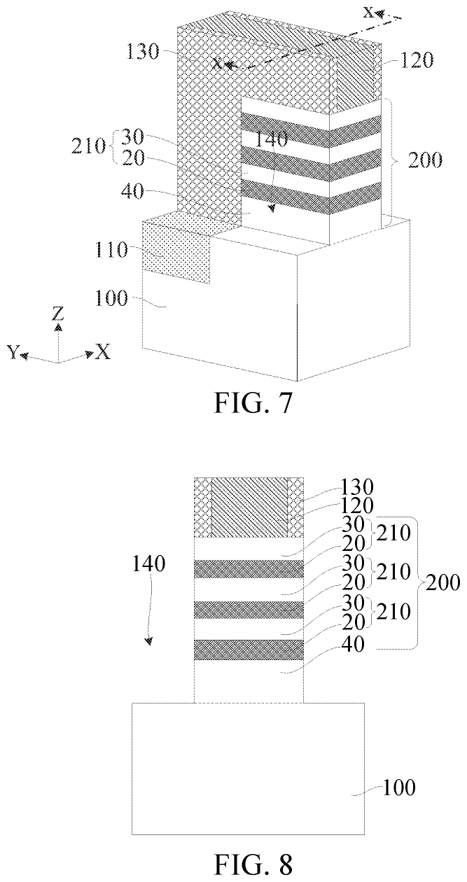

Refer to FIG. 7 and FIG. 8. FIG. 7 is a partial three-dimensional diagram, and FIG. 8 is a cross-sectional view of FIG. 7 along a direction xx. Grooves 140 are formed in the laminate structures 200 on two sides of the dummy gate structure 120.

The groove 140 is configured to provide a spatial position for formation of a source/drain structure. The laminate structure 200 is exposed out of a side wall of the groove 140, facilitating subsequent etching of a specified thickness of the sacrificial layer 20 along the horizontal direction, and also facilitating subsequent formation of a source/drain structure on the side wall where the first channel layer 30 and the second channel layer 40 are exposed out of the groove 140 by using an epitaxy process.

In this implementation, the base 100 is exposed out of a bottom of the groove 140. Specifically, a top surface of the protrusion is exposed out of the bottom of the groove 140.

In this implementation, an anisotropic etching process (for example, an anisotropic dry etching process) is adopted for etching laminate structures 200 on two sides of the dummy gate structure 120 and the gate side wall 130, facilitating improvement of quality of cross section profile of the groove 140.

In an example, the laminate structures 200 on two sides of the dummy gate structure 120 and the gate side wall 130 are removed to form the groove 140.

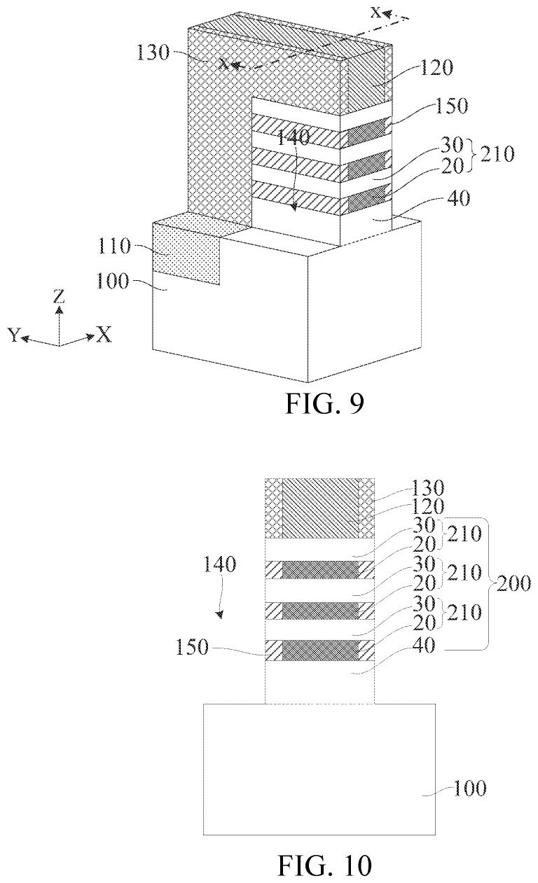

Refer to FIG. 9 and FIG. 10. FIG. 9 is a partial three-dimensional diagram, and FIG. is a cross-sectional view of FIG. 9 along a direction xx. In this implementation, after forming the groove 140, the formation method further includes: along the horizontal direction, etching part of thickness of the sacrificial layer 20 on the side wall of the groove 140 to form a trench (not shown in the figure), where the trench is enclosed by the first channel layer 30 and the sacrificial layer 20 that are adjacent to each other, or is enclosed by the base 100, the first channel layer 30 adjacent to the base 100, and the sacrificial layer 20; and filling the trench with an inner spacer (Inner spacer) 150.

Specifically, the trench is enclosed by the first channel layer 30 and the sacrificial layer 20 that are adjacent to each other, or is enclosed by the second channel layer 40, the first channel layer 30 adjacent to the second channel layer 40, and the sacrificial layer 20.

The trench is configured to provide a spatial position for formation of the inner spacer.

In this implementation, a vapor etching process is adopted for etching, along the horizontal direction, part of thickness of the sacrificial layer 20 on the side wall of the groove 140. The vapor etching process is an isotropic etching process, such that the sacrificial layer 20 can be etched along the horizontal direction, and the vapor etching process is easy to achieve a large etch selection ratio, helping to reduce difficulty for etching the sacrificial layer 20 and reducing possibility of damaging other film structures (for example, a first channel layer 30 and a second channel layer 40).

In this implementation, the sacrificial layer 20 is made of SiGe, the first channel layer 30 and the second channel layer 40 are made of Si, and the sacrificial layer 20 on the side wall of the groove 140 is vapor-etched by using HCl vapor. HCl vapor has a much high etching rate on SiGe material than on a Si material. This can effectively reduce the possibility of damage of the first channel layer 30 and the second channel layer 40.

In other implementations, when the first and second channel layers are made of SiGe and the sacrificial layer is made of Si, a dry etching process may be adopted for etching the sacrificial layer on the side wall of the groove along the horizontal direction. An etchant for the dry etching process may include a mixture of plasmas of CF₄, O₂, and N₂. The mixture of the plasmas has a large difference in a Si etching rate and a SiGe etching rate. This can also effectively reduce the possibility of damage of the first channel layer and the second channel layer.

Subsequently, a source/drain structure is formed in the groove 140, and gate structures are formed at the dummy gate structure 120 and the sacrificial layer 20. The inner spacer 150 is configured to isolate the source/drain structure from the gate structure, as well as to increase a distance between the gate structure and the source/drain structure, helping to reduce parasitic capacitance between the gate structure and the source/drain structure.

In this implementation, the inner spacer 150 is made of an insulating material for isolating the source/drain structure from the gate structure. In this implementation, the inner spacer 150 is made of silicon nitride, silicon oxide, silicon oxynitride, a low-k dielectric material, or an ultralow-k dielectric material. In an example, the inner spacer 150 is made of silicon nitride.

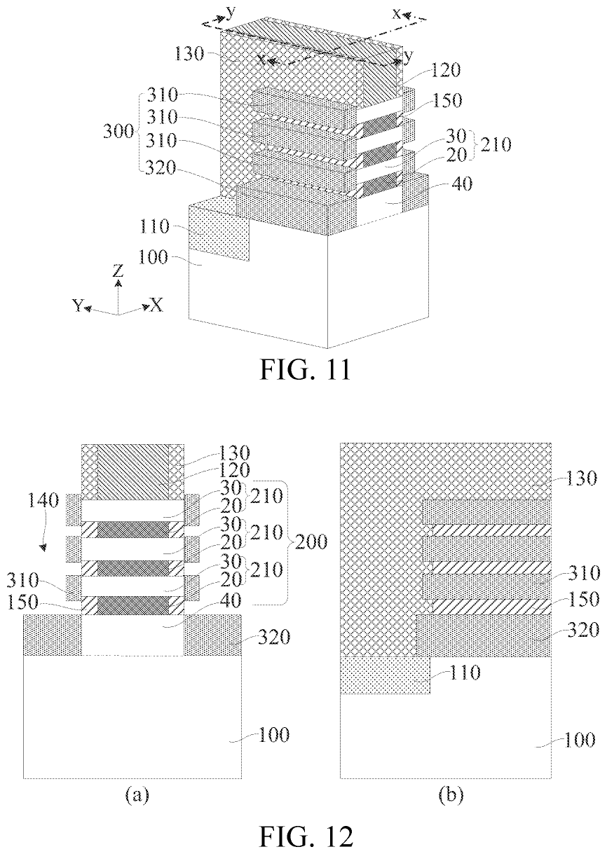

Refer to FIG. 11 and FIG. 12. FIG. 11 is a schematic diagram of a partial three-dimensional structure, FIG. 12(a) is a cross-sectional view of FIG. 11 along a direction xx, and FIG. 12(b) is a cross-sectional view of FIG. 11 along a direction yy. The source/drain structure 300 is formed in the groove 140, where the source/drain structure 300 includes a first source/drain doped layer 310 that covers the side wall of the first channel layer 30 exposed out of the groove 140.

The source/drain structure 300 is used as a source or a drain of a field effect transistor, and is configured to provide a current carrier source during work of the field effect transistor.

In this implementation, the resistance of the source/drain structure is reduced to increase the channel current in the channel layer without increasing the ion doping concentration of the source/drain structure, correspondingly helping to guarantee epitaxial growth quality of an epitaxy process for forming the source/drain structure 300, thereby improving the film forming quality of the source/drain structure 300 and facilitating optimization of the performance of the semiconductor structure.

In addition, in this implementation, the resistance of the source/drain structure is reduced to increase the channel current in the channel layer without increasing a projection area of the source/drain structure on the base, correspondingly facilitating miniaturization of the device size and also facilitating reduction of the manufacturing cost.

In this implementation, the source/drain structure 300 includes an ion-doped stress layer, where the stress layer is configured to provide stress for a channel region, thereby increasing a carrier mobility.

Specifically, the first source/drain doped layer 310 is configured to provide stress for the first channel layer 30.

In this implementation, during formation of a PMOS transistor, the source/drain structure 300 includes a P-type ion doped stress layer made of Si or SiGe. During formation of an NMOS transistor, the source/drain structure 300 includes an N-type ion doped stress layer made of Si or SiC.

In this implementation, along the horizontal direction, a width of the first source/drain doped layer 310 is smaller than a width of an opening of the groove 140, such that the groove 140 is not fully filled with the first source/drain doped layer 310. In the groove 140, there is still a remaining part of space in the side wall of the first source/drain doped layer 310, and the remaining space in the groove 140 can be used for providing a spatial position for subsequent formation of the source/drain plug, such that the source/drain plug is enabled to come into contact with the longitudinal side wall, facing away from the gate structure, of the first source/drain doped layer 310. Compared with the horizontal side wall of the first source/drain doped layer 310, the longitudinal side wall of the first source/drain doped layer 310 has a larger area, so that a contact area between the source/drain plug and the first source/drain doped layer 310 is increased. In addition, the source/drain plug fills the remaining space in the groove 140, which enables the source/drain plug to have a small size along the horizontal direction, facilitating reduction of a horizontal area occupied by the source/drain plug, thereby facilitating reduction of the size of the semiconductor structure.

It would be appreciated that along the horizontal direction, the width of the first source/drain doped layer 310 should not be too small or too large. If the width of the first source/drain doped layer 310 along the horizontal direction is too small, a volume of the first source/drain doped layer 310 is correspondingly too small, which is likely to affect stress of the first source/drain doped layer 310. In addition, subsequently a silicide layer is usually formed between the first source/drain doped layer 310 and the source/drain plug, a formation process of the silicide layer usually also consumes part of thickness of the first source/drain doped layer 310, and a too small width of the first source/drain doped layer 310 along the horizontal direction may result in a smaller volume of the remaining first source/drain doped layer 310 after the silicide layer is formed, causing an adverse effect to the performance of the semiconductor structure. A too large width of the width of the first source/drain doped layer 310 along the horizontal direction is likely to cause a too small remaining space in the groove 140. As a result, when a source/drain plug is subsequently formed in the remaining space in the groove 140, the space for forming the source/drain plug is too small, which accordingly increases a forming difficulty of the source/drain plug. Therefore, in this implementation, along the horizontal direction, a width of the first source/drain doped layer 310 is 10% to 90% of a width of the groove 140.

In an implementation, the first source/drain doped layers 310 located on the side walls of the adjacent first channel layers 30 are spaced apart. In a subsequent formation process of the source/drain plug, when the source/drain plug is further in contact with the longitudinal side wall facing away from the gate structure, the side wall along the horizontal first side and the side wall along the horizontal second side of the first source/drain doped layer 310, the first source/drain doped layers 310 on the side walls of the adjacent first channel layers 30 have no contact with each other, so that during work of the device, current is prevented from flowing in a direction (as indicated by a direction Z in FIG. 11) perpendicular to the base 100 in the source/drain structure 300, and thus the current flows to each first channel layer 30 through only the source/drain plug, correspondingly significantly reducing a voltage drop consumed in a route through which the current flows to each first channel layer 30, increasing the channel current value in each first channel layer 30, and especially significantly increasing the channel current value in the first channel layer 30 closer to the base 100.

In other implementations, on the basis of an actual process for forming the source/drain structure, the first source/drain doped layers on the side walls of the adjacent first channel layers can also be in contact with each other. Therefore, during subsequent formation of an interlayer dielectric layer covering the source/drain structure, the interlayer dielectric layer does not need to fill a gap between the first source/drain doped layers on the side walls of the adjacent first channel layers, helping to reduce a technological difficulty for forming the interlayer dielectric layer, and correspondingly improving the technological compatibility.

In this implementation, the laminate structure 200 further includes a second channel layer 40. The step of forming the source/drain structure 300 in the groove 140 includes: forming a first source/drain doped layer 310 located on a side wall of the first channel layer 30 exposed out of the groove 140, and a second source/drain doped layer 320 located on a side wall of the second channel layer 40 exposed out of the groove 140, where the second source/drain doped layer 320 is further formed on the base 100 at the bottom of the groove 140; and along the horizontal direction, an end portion of the second source/drain doped layer 320 protrudes out of an end portion of the first source/drain doped layer 310.

The second source/drain doped layer 320 is configured to provide stress for the second channel layer 40, thereby increasing a carrier mobility in the second channel layer 40.

In this implementation, along the horizontal direction, the width of the first source/drain doped layer 310 is smaller than the width of the opening of the groove 140, the second source/drain doped layer 320 is further formed on the base 100 at the bottom of the groove 140, and the end portion of the second source/drain doped layer 320 along the horizontal direction protrudes out of the end portion of the first source/drain doped layer 310, such that there is still a remaining space in the groove 140 for providing a space for subsequent formation of the source/drain plug. In addition, the subsequent source/drain plug may be in contact with the top of the second source/drain doped layer 320, not only implementing electric connection between the source/drain plug and the second source/drain doped layer 320, but also preventing contact between the source/drain plug and the base 100 at the bottom of the groove 140.

In this implementation, the second source/drain doped layer 320 and the first source/drain doped layer 310 are made of a same material, and are also the same in doping type.

In an implementation, the second source/drain doped layer 320 and the first source/drain doped layer 310 are spaced apart. Correspondingly, during a subsequent formation process of the source/drain plug, when the source/drain plug is at least in contact with the tops of the first source/drain doped layer 310 and second source/drain doped layer 320 as well as the longitudinal side wall, facing away from the gate structure, of the first source/drain doped layer 310, the second source/drain doped layer 320 and the first source/drain doped layer 310 have no contact with each other, so that during work of the device, current is prevented from flowing to the second channel layer 40 along a direction (as indicated by a direction Z in FIG. 11) perpendicular to the base 100 in the source/drain structure 300, and thus the current flows to the second channel layer 40 through only the source/drain plug, correspondingly significantly reducing a voltage drop consumed in a route through which the current flows to the second channel layer 40, and significantly increasing the channel current value in the second channel layer 40.

In other implementations, on the basis of an actual process for forming the source/drain structure, the second source/drain doped layer and the first source/drain doped layer can also be in contact with each other. Therefore, during subsequent formation of an interlayer dielectric layer covering the source/drain structure, the interlayer dielectric layer does not need to fill a gap between the second source/drain doped layer and the first source/drain doped layer, helping to reduce a technological difficulty for forming the interlayer dielectric layer, and correspondingly improving the technological compatibility.

It would be appreciated that this implementation is described by using an example in which the laminate structure 200 further includes the second channel layer 40, and correspondingly the source/drain structure 300 further includes the second source/drain doped layer 320 located on the side wall of the second channel layer 40. In other implementations, when a laminate structure includes only a plurality of channel laminates sequentially stacked from bottom to top, a source/drain structure correspondingly includes only a first source/drain doped layer located on a side wall of a first channel layer.

In this implementation, the source/drain structure 300 is formed by using an epitaxy process. Specifically, epitaxial growth is performed based on the first channel layer 30, second channel layer 40 and base 100 exposed out of the groove 140.

In this implementation, parameters of the epitaxy process include: a process temperature of 550° C. to 800° C., a gas flow rate of 10 standard cubic centimeters per minute (sccm) to 200 sccm, and a process time of 60 seconds to 3600 seconds. The technological parameters of the epitaxy process being set within the above ranges ensures that the first source/drain doped layer 310 is not too thick, such that there is still a reserved remaining space in the groove 140 for forming the source/drain plug.

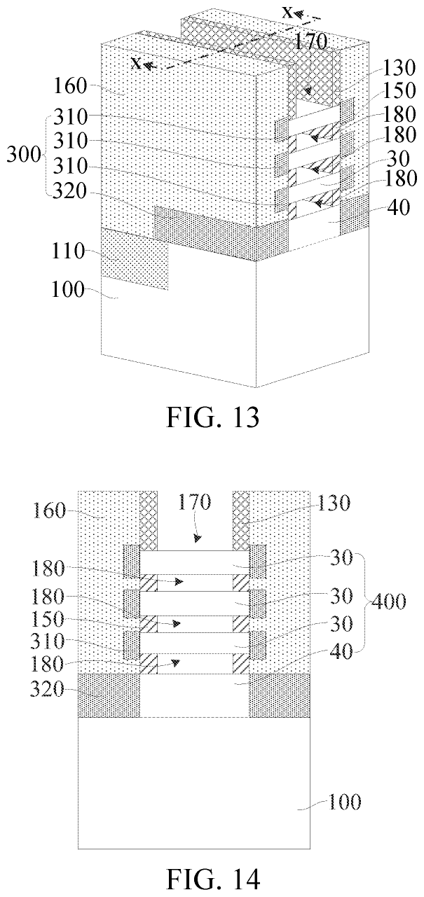

Refer to FIG. 13 and FIG. 14. FIG. 13 is a partial three-dimensional diagram, and FIG. 14 is a cross-sectional view of FIG. 13 along a direction xx. In this implementation, the formation method further includes: after forming the source/drain structure 300, forming an interlayer dielectric layer 160 on the base 100 at a side portion of the dummy gate structure 120 to cover the source/drain structure 300.

The interlayer dielectric layer 160 is configured to isolate adjacent devices and is further configured to support the first channel layer 30 during a subsequent removal process of the dummy gate structure 120 and the sacrificial layer 20, so as to implement arrangement of suspended and spaced first channel layers 30. In this implementation, the interlayer dielectric layer 160 is made of silicon oxide. The interlayer dielectric layer 160 may alternatively be made of another insulating material.

In this implementation, the interlayer dielectric layer 160 further exposes the top of the dummy gate structure 120, so as to facilitate subsequent removal of the dummy gate structure 120.

In this implementation, the first source/drain doped layers 310 located on the side walls of the adjacent first channel layers 30 are spaced apart, and correspondingly the interlayer dielectric layer 160 further fills a space between the adjacent first source/drain doped layers 310. In this implementation, the source/drain structure 300 further includes a second source/drain doped layer 320, the second source/drain doped layer 320 and the adjacent first source/drain doped layer 310 are spaced apart, and correspondingly the interlayer dielectric layer 160 further fills a space between the second source/drain doped layer 320 and the adjacent first source/drain doped layer 310.

In this implementation, the process for forming the interlayer dielectric layer 160 includes: at least one of a flow chemical vapor deposition (FCVD) process and an atomic layer deposition (ALD) process. FCVD and ALD both have a high gap filling capability, which is conducive to ensuring that the interlayer dielectric layer 160 can fill a space between the adjacent first source/drain doped layers 310 and a space between the second source/drain doped layer 320 and the adjacent first source/drain doped layer 310, thereby improving a film forming quality of the interlayer dielectric layer 160.

Specifically, the step for forming the interlayer dielectric layer 160 includes: forming a dielectric material layer (not shown in the figure) covering the source/drain structure 300 and the dummy gate structure 120 on the base 100 by using a deposition process; and removing the dielectric layer on the top of the dummy gate structure 120 by using a planarization process, where the remaining dielectric material layer is used as the interlayer dielectric layer 160.

The deposition process may be at least one of a flow chemical vapor deposition (FCVD) process and an atomic layer deposition (ALD) process.

Still refer to FIG. 13 and FIG. 14. FIG. 13 is a partial three-dimensional diagram, and FIG. 14 is a cross-sectional view of FIG. 13 along a direction xx. The dummy gate structure 120 is removed to form a gate opening 170 to expose the channel laminate 210.

The gate opening 170 is configured to provide a spatial position for formation of a gate structure. The gate opening 170 exposes the channel laminate 210, such that the sacrificial layer 20 can be removed via the gate opening 170 subsequently.

In this implementation, the gate opening 170 stretches across the laminate structure 200, and the gate opening 170 is located in the interlayer dielectric layer 160.

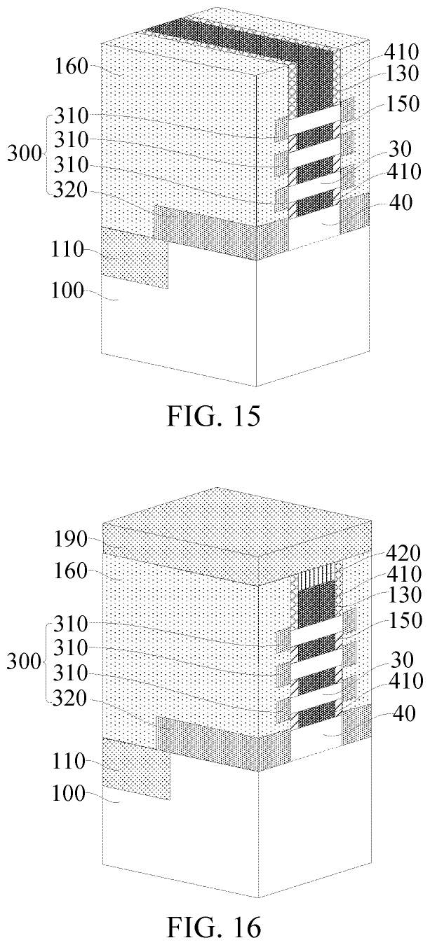

Still refer to FIG. 14 and FIG. 15. The sacrificial layer 20 in the channel laminate 210 is removed via the gate opening 170, such that the adjacent first channel layers 30 as well as the base 100 and the first channel layer 30 adjacent to the base 100 are surrounded to form a through groove 180.

In this implementation, the sacrificial layer 20 in the channel laminate 210 is removed, such that the adjacent first channel layers 30 as well as the second channel layer 40 and the first channel layer 30 adjacent to the second channel layer 40 are surrounded to form the through groove 180.

The through groove 180 and the gate opening 170 jointly provide a spatial position for formation of the gate structure. The through groove 180 communicates with the gate opening 170.

The sacrificial layer 20 is removed after the source/drain structure 300 is formed. Therefore, after the sacrificial layer 20 is removed, along the horizontal direction, two ends of the first channel layer 30 are connected to the first source/drain doped layer 310, and are suspended in the gate opening 170, so that a subsequent gate structure can surround the first channel layer 30.

In this implementation, after the sacrificial layer 20 is removed, the first channel layers are spaced apart, and the plurality of first channel layers 30 spaced part are configured to form the channel structure layer 400. In this implementation, the channel structure layer 400 further includes: a second channel layer 40 located between the base 100 and the first channel layer 30 and spaced apart from the first channel layer 30.

In this implementation, the sacrificial layer 20 is removed by using a vapor etching process. Specifically, the first channel layer 30 and the second channel layer 40 are made of Si, and the sacrificial layer 20 is made of SiGe. Therefore, the sacrificial layer 20 exposed out of the gate opening 170 is removed by using HCl vapor.

FIG. 15 shows a partial three-dimensional diagram, where gate structures 410 are formed in the gate opening 170 and the through groove 180 to surround the first channel layer 30.

During work of the device, the gate structure 410 is configured to control on and off of the conducting channel.

In this implementation, the gate structure 410 is a metal gate structure. The gate structure 410 includes a high-k gate dielectric layer (not shown in the figure), a work function layer (not shown in the figure) located on the high-k gate dielectric layer, and a gate electrode layer (not shown in the figure) that is located on the work function layer and fills the through groove 180 and the gate opening 170.

The high-k gate dielectric layer is configured to implement electrical isolation between the work function layer and the channel and between the gate electrode layer and the channel. The high-k gate dielectric layer is made of a high-k dielectric material. The high-k gate dielectric layer may alternatively be made of a material selected from ZrO₂, HfSiO, HfSiON, HfTaO, HfTiO, HfZrO, or Al₂O₃.

The work function layer is configured to adjust a work function of the gate structure 410 so as to adjust a voltage threshold of the field effect transistor. During formation of an NMOS transistor, the work function layer is an N-type work function layer, and the work function layer is made of one or more of titanium aluminide, tantalum carbide, aluminum, or titanium carbide. During formation of a PMOS transistor, the work function layer is a P-type work function layer, and the work function layer is made of one or more of titanium nitride, tantalum nitride, titanium carbide, tantalum silicon nitride, titanium silicon nitride, and tantalum carbide.

The gate electrode layer is an external electrode of the gate structure 410 to be electrically connected to an external circuit. The gate electrode layer is made of a conductive material, for example, W, Al, Cu, Ag, Au, Pt, Ni, or Ti.

In this implementation, the gate structure 410 being a metal gate structure is used as an example for description. In other implementations, according to actual process requirements, the gate structure may also be another type of gate structure, for example, a polysilicon gate structure or an amorphous silicon gate structure.

Referring to FIG. 16 to FIG. 20, source/drain plugs 350 are formed on two sides of the gate structure 410 and are in contact with the top of the source/drain structure 300; and in addition, the source/drain plugs 350 are further in contact with at least one of a longitudinal side wall facing away from the gate structure 410, a side wall along a horizontal first side and a side wall along a horizontal second side of the first source/drain doped layer 310.

The source/drain plug 350 is configured to implement electric connection between the source/drain structure 300 and an external circuit or other interconnected structures. The source/drain plug 350 is made of a conductive material, for example, one or more of Cu, Co, Ru, RuN, W, and Al.

As compared with a solution in which the source/drain plug is in contact with only the top of the source/drain doped layer, the source/drain plug 350 and the first source/drain doped layer 310 formed in this implementation further have a contact surface along a direction perpendicular to a surface of the base 100, and the source/drain plug 350 can be in contact with all the first source/drain doped layers 310 located on side walls of the first channel layers 30. During work of a device, the current can correspondingly directly flow to each first channel layer 30 through the side wall of the first source/drain doped layer 310 by the source/drain plug 350, thereby avoiding flowing of the current along a direction perpendicular to the base 100 in the source/drain structure 300. A material of the source/drain plug 350 has a significantly smaller resistivity than a material of the source/drain structure 300, so that the current directly flows to each first channel layer 30 through the source/drain plug 350, facilitating reduction of parasitic resistance, correspondingly reducing a voltage drop consumed in a route through which the current flows to each first channel layer 30, increasing a channel current value in each first channel layer 30, and especially significantly increasing the channel current value in the first channel layer 30 closer to the base 100, thereby increasing a drive current of the device and optimizing the performance of the semiconductor structure.

In an example, along the horizontal direction, the end portion of the second source/drain doped layer 320 protrudes out of the end portion of the first source/drain doped layer 310. Correspondingly, the source/drain plug 350 is at least in contact with the tops of the first source/drain doped layer 310 and second source/drain doped layer 320 as well as the longitudinal side wall, facing away from the gate structure 410, of the first source/drain doped layer 310.

Compared with the first channel layer 30, the second channel layer 40 is closer to the base 100. The second channel layer 40 is a lowermost channel layer in the channel structure layer 400. The source/drain plug 350 is in contact with the top of the source/drain doped layer 320, so that the source/drain plug 350 is electrically connected to the second source/drain doped layer 320, thus current can directly flow to the second channel layer 40 through the source/drain plug 350, thereby significantly increasing the channel current in the second channel layer 40. In addition, contact between the source/drain plug 350 and the base 100 at the bottom of the groove 140 is also prevented.

In addition, compared with the side wall along the horizontal first side or the side wall along the horizontal second side of the first source/drain doped layer 310, the longitudinal side wall, facing away from the gate structure 410, of the first source/drain doped layer 310 has a larger area; and the source/drain plug 350 is in contact with the longitudinal side wall, facing away from the gate structure 410, of the first source/drain doped layer 310, helping to ensure that the source/drain plug 350 does not have a too large volume and also increasing a contact area between the source/drain plug 350 and the first source/drain doped layer 310, thereby reducing contact resistance of the source/drain plug 350 and the first source/drain doped layer 310.

In an example, the source/drain plug 350 is further in contact with at least one of a side wall 38 along a horizontal first side and a side wall along a horizontal second side of the second source/drain doped layer 320, helping to increase a contact area between the source/drain plug 350 and the second source/drain doped layer 320, and correspondingly reducing contact resistance of the source/drain plug 350 and the second source/drain doped layer 320.

In an implementation, the source/drain plug 350 is in contact with all the tops of the first source/drain doped layer 310 and second source/drain doped layer 320, the longitudinal side wall 35, facing away from the gate structure 410, of the first source/drain doped layer 310, the side wall 36 along the horizontal first side and the side wall along the horizontal second side of the first source/drain doped layer 310, as well as the side wall 38 along the horizontal first side and the side wall along the horizontal second side of the second source/drain doped layer 320, so that the source/drain plug 350 can be in contact with all the top and side walls of the exposed first source/drain doped layer 310 as well as the top and side walls of the exposed second source/drain doped layer 320, helping to significantly increase a contact area between the source/drain plug 350 and the first source/drain doped layer 310 and a contact area between the source/drain plug 350 and the second source/drain doped layer 320, thereby significantly reducing contact resistance of the source/drain plug 350 and the source/drain structure 300, and improving the performance of the semiconductor structure.

In this implementation, the source/drain plug 350 penetrates through the interlayer dielectric layer 160 at the top of the source/drain structure 300.

The following describes in detail the steps for forming the source/drain plug 350 in this implementation with reference to the accompanying drawings.

As shown in FIG. 16 to FIG. 18, source/drain contact holes 340 are formed in two sides of the gate structure 410 to expose the top of the source/drain structure 300 and also expose at least one of a longitudinal side wall facing away from the gate structure 410, a side wall along a horizontal first side and a side wall along a horizontal second side of the first source/drain doped layer 310. The source/drain contact hole 340 is configured to provide a spatial position for formation of the source/drain plug.

In an example, the source/drain contact hole 340 exposes the top of the source/drain structure 300 and also exposes at least one of a longitudinal side wall 35 facing away from the gate structure 410, a side wall 36 along a horizontal first side and a side wall (not shown in the figure) along a horizontal second side of the first source/drain doped layer 310, thereby increasing a surface area of the exposed source/drain structure 300 so as to increase a contact area between the source/drain structure 300 and a subsequent source/drain plug.

In this implementation, the source/drain contact hole 340 also exposes the top of the second source/drain doped layer 320, so that subsequently the source/drain plug can come into contact with the top of the second source/drain doped layer 320, thereby enabling current to directly flow to the second channel layer 40 through the source/drain plug.

In an example, the source/drain contact hole 340 also exposes at least one of a side wall 38 along a horizontal first side and a side wall along a horizontal second side of the second source/drain doped layer 320, thereby increasing a surface area of the exposed second source/drain doped layer 320 so as to increase a contact area between the second source/drain doped layer 320 and the source/drain plug.

In other implementations, the source/drain contact hole may also only expose any one of a side wall along a horizontal first side and a side wall along a horizontal second side of the second source/drain doped layer.

It would be appreciated that FIG. 16 shows a partial three-dimensional diagram. In this implementation, before the source/drain contact hole 340 is formed, the formation method further includes: removing part of thickness of a material at the top of the gate structure 410, forming an etch stop layer 420 at the top of the gate structure 410; and forming a metal dielectric layer 190 on the interlayer dielectric layer 160 to cover the etch stop layer 420.

The etch stop layer 420 is configured to protect the top of the gate structure 410 so as to prevent mistaken etching of the gate structure 410 during formation of the source/drain contact hole 340, thereby helping to avoid bridging of the source/drain plug and the gate structure 410.

The etch stop layer 420 is made of a material that has etching selectivity with a material of the metal dielectric layer 190 or interlayer dielectric layer 160, so as to ensure that an etching process for forming the source/drain contact hole 340 is unlikely to cause mistaken etching of the etch stop layer 420.

In this implementation, the etch stop layer 420 is made of one or more of silicon nitride, silicon carbide, silicon carbonitride, silicon oxy-carbonitride, silicon oxynitride, boron nitride, and boron carbonitride. In an example, the etch stop layer 420 is made of silicon carbide.

The metal dielectric layer 190 is configured to implement electrical isolation between the source/drain plugs. The metal dielectric layer 190 is made of a dielectric material, for example, one or more of silicon oxide, silicon nitride, silicon oxynitride, silicon oxycarbide, silicon carbonitride, silicon oxy-carbonitride, a low-k dielectric material, and an ultralow-k dielectric material.

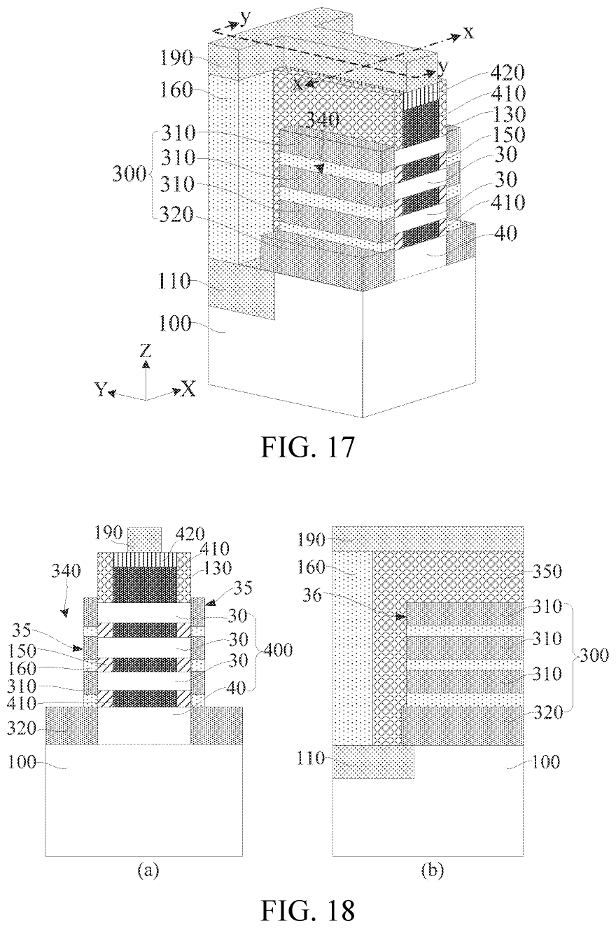

Therefore, as shown in FIG. 17 and FIG. 18, FIG. 17 is a partial three-dimensional diagram, FIG. 18(a) is a cross-sectional view of FIG. 17 along a direction xx, and FIG. 18b) is a cross-sectional view of FIG. 17 along a direction yy. In this implementation, in the step of forming the source/drain contact hole 340, the source/drain contact hole 340 penetrates through the interlayer dielectric layer 160 and the metal dielectric layer 190 at the upper portion of the source/drain structure 300.

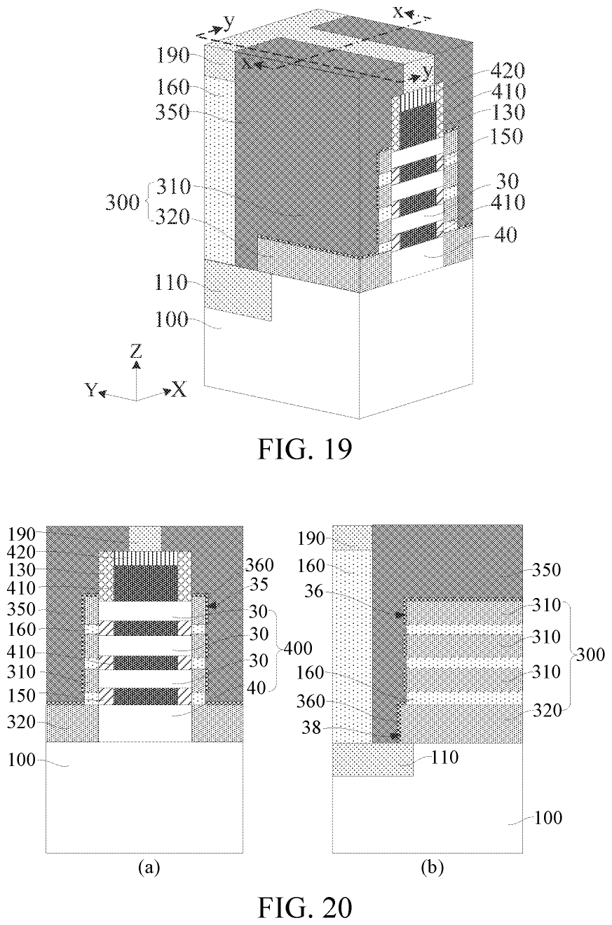

As shown in FIG. 19 and FIG. 20, FIG. 19 is a partial three-dimensional structure, FIG. 20(a) is a cross-sectional view of FIG. 19 along a direction xx, and FIG. 20(b) is a cross-sectional view of FIG. 19 along a direction yy. The source/drain contact hole 340 is filled with the source/drain plug 350.

In this implementation, the process for forming the source/drain plug 350 includes a chemical vapor deposition process.

Specifically, in an example, the step of filling the source/drain contact hole 340 with the source/drain plug 350 includes: filling the source/drain contact hole 340 with a source/drain plug material (not shown in the figure), where the source/drain plug material is further formed on the metal dielectric layer 190; and removing the source/drain plug material on the metal dielectric layer 190, where the remaining source/drain plug material filling the source/drain contact hole 340 is used as the source/drain plug 350.

In this implementation, a process for filling the source/drain contact hole 340 with the source/drain plug material includes: a chemical vapor deposition process. The process for filling the source/drain plug material achieves a good gap filling capability, which is conducive to improving filling capability and filling quality of the source/drain plug material in the source/drain contact hole 340.

In this implementation, a planarization process (for example, a chemical mechanical planarization process) is used to remove the source/drain plug material on the metal dielectric layer 190, which is conducive to improving removal efficiency of the source/drain plug material on the metal dielectric layer 190 as well as increasing flatness of the top surface of the source/drain plug 350 and the metal dielectric layer 190.

In this implementation, the formation method further includes: after forming the source/drain contact hole 340 and before filling the source/drain contact hole 340 with the source/drain plug 350, forming a silicide layer 360 on a surface of the source/drain structure 300 exposed out of the source/drain contact hole 340.

The silicide layer 360 is configured to reduce contact resistance between the source/drain plug 350 and the source/drain structure 300. In addition, during work of the device, current flows through a surface of the silicide layer 360 via the source/drain plug 350, in other words, the current can flow through the surface of the source/drain structure 300 in contact with the source/drain plug 350 and thus flows to each channel layer. In this implementation, the current can flow through the surface of the source/drain structure 300 in contact with the source/drain plug 350 and thus flows to the second channel layer 40 and each first channel layer 30.

In this implementation, the silicide layer 360 may be made of a nickel-silicon compound, a cobalt-silicon compound, or a titanium-silicon compound.

Although embodiments and implementations of the present disclosure is described above, the present disclosure is not limited thereto. Any person skilled in the art can make various changes and modifications without departing from the spirit and the scope of the present disclosure. Therefore, the protection scope of the present disclosure should be subject to the scope defined by the claims.

What is claimed is:

1. A semiconductor structure, comprising:
a base;
a channel structure layer located on the base, wherein the channel structure layer comprises a plurality of first channel layers sequentially spaced apart from bottom to top, the first channel layers extend along a horizontal direction, and a direction parallel to the base and perpendicular to the horizontal direction is a longitudinal direction;
gate structures stretching across the channel structure layer and surrounding the plurality of first channel layers, wherein the gate structures fill a space between adjacent first channel layers of the plurality of first channel layers and a space between the base and the first channel layer of the plurality of first channel layers adjacent to the base;
source/drain structures located on two sides of a gate structure and covering a side wall of the channel structure layer, wherein the source/drain structure comprises a first source/drain doped layer located on a side wall of the first channel layer of the plurality of first channel layers along the horizontal direction; and
source/drain plugs located on two sides of the gate structure and in contact with tops of the source/drain structures, wherein the source/drain plug is further in contact with at least one of a longitudinal side wall facing away from the gate structure, a side wall along a horizontal first side, and a side wall along a horizontal second side of the first source/drain doped layer.

2. The semiconductor structure according to claim 1, wherein the channel structure layer further comprises:
a second channel layer located between the base and a first channel layer and spaced apart from the first channel layer, wherein the gate structure fills a space between adjacent first channel layers and a space between the second channel layer and the first channel layer adjacent to the second channel layer;
the source/drain structure further comprises:
a second source/drain doped layer located on a side wall of the second channel layer along the horizontal direction, wherein the second source/drain doped layer is further located on a top surface of the base on two sides of the second channel layer, and along the horizontal direction, an end portion of the second source/drain doped layer protrudes out of an end portion of the first source/drain doped layer; and
the source/drain plug is at least in contact with tops of the first and second source/drain doped layers, and a longitudinal side wall, facing away from the gate structure, of the first source/drain doped layer.

3. The semiconductor structure according to claim 2, wherein the source/drain plug is further in contact with at least one of a side wall along a horizontal first side and a side wall along a horizontal second side of the second source/drain doped layer.

4. The semiconductor structure according to claim 2, wherein along the horizontal direction, a width of the first source/drain doped layer is 10% to 90% of a width of the second source/drain doped layer.

5. The semiconductor structure according to claim 2, wherein the second source/drain doped layer and the first source/drain doped layer are spaced apart, or are in contact with each other.

6. The semiconductor structure according to claim 1, wherein the first source/drain doped layers located on side walls of adjacent first channel layers are spaced apart, or are in contact with each other.

7. The semiconductor structure according to claim 6, wherein the semiconductor structure further comprises:
an interlayer dielectric layer located on the base at a side portion of the gate structure, wherein the interlayer dielectric layer covers the source/drain structure and fills a space between adjacent first channel layers, wherein when the first source/drain doped layers on the side walls of adjacent first channel layers are spaced apart, the interlayer dielectric layer further fills a space between adjacent first source/drain doped layers; and
the source/drain plug penetrates through the interlayer dielectric layer on top of the source/drain structure.

8. The semiconductor structure according to claim 1, wherein the semiconductor structure further comprises:
a silicide layer located between the source/drain plug and a surface of the source/drain structure.

9. A formation method of a semiconductor structure, comprising:
providing a base, wherein a laminate structure is formed on the base and comprises a plurality of channel laminates sequentially stacked from bottom to top, each of the plurality of channel laminate comprises a sacrificial layer and a first channel layer located on the sacrificial layer, the first channel layer extends along a horizontal direction, and a direction parallel to the base and perpendicular to the horizontal direction is a longitudinal direction;
forming a dummy gate structure stretching across the laminate structure on the base;
forming grooves in parts, on two sides of the dummy gate structure, of the laminate structure;
forming a source/drain structure in the groove, wherein the source/drain structure comprises a first source/drain doped layer covering a side wall of the first channel layer exposed out of the groove;
removing the dummy gate structure and forming a gate opening to expose a channel laminate;
removing the sacrificial layer in the channel laminate via the gate opening, such that adjacent first channel layers as well as the base and the first channel layer adjacent to the base are surrounded to form a through groove;
forming gate structures in the gate opening and the through groove to surround the first channel layer; and
forming source/drain plugs on two sides of the gate structure, wherein the source/drain plug is in contact with a top of the source/drain structure, and the source/drain plug is further in contact with at least one of a longitudinal side wall facing away from the gate structure, a side wall along a horizontal first side and a side wall along a horizontal second side of the first source/drain doped layer.

10. The formation method of a semiconductor structure according to claim 9, wherein the laminate structure further comprises a second channel layer located between the base and the channel laminate;
in the step of forming the groove, the base is exposed out of a bottom of the groove;
the step of forming the source/drain structure in the groove comprises:
forming a first source/drain doped layer located on a side wall of the first channel layer exposed out of the groove, and a second source/drain doped layer located on a side wall of the second channel layer exposed out of the groove, wherein the second source/drain doped layer is further formed on the base at the bottom of the groove; and along the horizontal direction, an end portion of the second source/drain doped layer protrudes out of an end portion of the first source/drain doped layer;
in the step of removing the sacrificial layer in the channel laminate, the adjacent first channel layers as well as the second channel layer and the first channel layer adjacent to the second channel layer are surrounded to form the through groove; and
in the step of forming the source/drain plug, the source/drain plug is at least in contact with tops of the first and second source/drain doped layers, and a longitudinal side wall, facing away from the gate structure, of the first source/drain doped layer.

11. The formation method of a semiconductor structure according to claim 10, wherein in the step of forming the source/drain plug, the source/drain plug is further in contact with at least one of a side wall along a horizontal first side and a side wall along a horizontal second side of the second source/drain doped layer.

12. The formation method of a semiconductor structure according to claim 9, wherein the step of forming the source/drain plug comprises:
forming source/drain contact holes in two sides of the gate structure to expose the top of the source/drain structure and also expose at least one of a longitudinal side wall facing away from the gate structure, a side wall along a horizontal first side and a side wall along a horizontal second side of the first source/drain doped layer; and
filling the source/drain contact hole with the source/drain plug.

13. The formation method of a semiconductor structure according to claim 12, wherein the formation method of a semiconductor structure further comprises:
after forming the source/drain contact hole and before filling the source/drain contact hole with the source/drain plug, forming a silicide layer on a surface of the source/drain structure exposed out of the source/drain contact hole.

14. The formation method of a semiconductor structure according to claim 9, wherein the source/drain structure is formed using an epitaxy process.

15. The formation method of a semiconductor structure according to claim 14, wherein parameters of the epitaxy process comprise:
a process temperature of 550° C. to 800° C., a gas flow rate of 10 standard cubic centimeters per minute (sccm) to 200 sccm, and a process time of 60 seconds to 3600 seconds.

16. The formation method of a semiconductor structure according to claim 10, wherein the second source/drain doped layer and the first source/drain doped layer are spaced apart, or are in contact with each other.

17. The formation method of a semiconductor structure according to claim 9, wherein along the horizontal direction, a width of the first source/drain doped layer is less than a width of an opening of the groove.

18. The formation method of a semiconductor structure according to claim 9, wherein along the horizontal direction, a width of the first source/drain doped layer is 10% to 90% of a width of an opening of the groove.

19. The formation method of a semiconductor structure according to claim 9, wherein the first source/drain doped layers located on side walls of the adjacent first channel layers are spaced apart, or are in contact with each other.

20. The formation method of a semiconductor structure according to claim 19, wherein the formation method of a semiconductor structure further comprises:
after forming the source/drain structure and before removing the dummy gate structure, forming an interlayer dielectric layer on the base at a side portion of the dummy gate structure to cover the source/drain structure, wherein when the first source/drain doped layers on the side walls of the adjacent first channel layers are spaced apart, the interlayer dielectric layer further fills a space between adjacent first source/drain doped layers; and
in the step of forming the source/drain plug, the source/drain plug penetrates through the interlayer dielectric layer at the top of the source/drain structure.
